(19) United States
(12) Patent Application Publication
(10) Pub. No.: US 2026/0181888 A1
(43) Pub. Date: Jun. 25, 2026

(54) THREE-DIMENSIONAL SEMICONDUCTOR MEMORY DEVICE AND METHOD OF FABRICATING THE SAME

(71) Applicant: SK hynix Inc., Gyeonggi-do (KR)

(72) Inventors: Tong Zhang, San Jose, CA (US); Sung-Taeg KANG, San Jose, CA (US); Sungwon LIM, San Jose, CA (US); Agus Tjandra, San Jose, CA (US)

(21) Appl. No.: 18/987,879

(22) Filed: Dec. 19, 2024

(51) Int. Cl. H10B 43/27

(52) U.S. Cl. CPC H10B 43/27

(57) ABSTRACT

A method of fabricating a semiconductor memory device includes forming a stack structure including alternately stacked interlayer insulating layers and sacrificial layers on a substrate; forming a channel hole penetrating the stack structure; forming a memory layer and a channel layer vertically disposed in the channel hole; forming a gap-filling layer to fill a remainder of the channel hole; forming an exposed portion of the channel layer by recessing an uppermost interlayer insulating layer of the interlayer insulating layers, the memory layer, and the gap-filling layer; forming a mesa structure by performing an epitaxial growth process on the exposed portion of the channel layer; replacing the sacrificial layers with gate electrode layers; and forming a contact plug disposed to contact the mesa structure.

### BACKGROUND

### 1. Technical Field

Embodiments of the present disclosure relate to a semiconductor memory device, and more particularly to a three-dimensional semiconductor memory device and a method of fabricating a three-dimensional semiconductor memory device.

### 2. Related Art

Semiconductor memory devices may include a plurality of memory cells capable of storing data. In order to improve a degree of integration of semiconductor memory devices, three-dimensional (3D) memory devices in which memory cells are arranged in three-dimensions on a substrate have been proposed.

In this context, embodiments of the present disclosure arise.

### SUMMARY

Embodiments of the present disclosure are directed to a three-dimensional semiconductor memory device and a method of fabricating a three-dimensional semiconductor memory device capable of reducing channel to bit line contact resistance by enlarging a channel layer without complicated and expensive processes.

In accordance with an embodiment of the present disclosure, there is provided a method of fabricating a three-dimensional semiconductor memory device. The method may include forming a stack structure including alternately stacked interlayer insulating layers and sacrificial layers on a substrate; forming a channel hole penetrating the stack structure; forming a memory layer and a channel layer vertically disposed in the channel hole; forming a gap-filling layer to fill a remainder of the channel hole; forming an exposed portion of the channel layer by recessing an uppermost interlayer insulating layer of the interlayer insulating layers, the memory layer, and the gap-filling layer; forming a mesa structure by performing an epitaxial growth process on the exposed portion of the channel layer; replacing the sacrificial layers with gate electrode layers; and forming a contact plug disposed to contact the mesa structure.

In accordance with an embodiment of the present disclosure, there is provided a three-dimensional semiconductor memory device. The three-dimensional semiconductor memory device may include a plurality of interlayer insulating layers and a plurality of gate electrode layer, which are alternately stacked to form a stack structure; a memory layer and a channel polysilicon layer vertically disposed within the stack structure; a silicon mesa disposed to be connected to the channel polysilicon layer, the silicon mesa being formed by a selective silicon epitaxial growth of the channel polysilicon layer; and a contact plug disposed to contact the silicon mesa.

These and other features and advantages of the embodiments of the present disclosure will become apparent to those skilled in the art from the following detailed description in conjunction with the following drawings.

### BRIEF DESCRIPTION OF THE DRAWINGS

FIG. 1 is a schematic circuit diagram illustrating a memory cell string of a semiconductor memory device.

FIG. 2 is a perspective view illustrating a structure of a semiconductor memory device.

FIGS. 3A to 3G are cross-sectional views illustrating a method of fabricating a three-dimensional semiconductor memory device, in accordance with an embodiment of the present disclosure.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The embodiments of the present disclosure are described herein with reference to cross-section and/or plan illustrations of the embodiments. However, the embodiments of the present disclosure should not be construed as limiting the inventive concept. Although a few embodiments of the present disclosure will be shown and described, it will be appreciated by those of ordinary skill in the art that changes may be made in these embodiments without departing from the principles and spirit of the present disclosure.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the spirit and scope of the present disclosure.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element. When a first element is referred to as being “on” a second element, it refers to a case where the first element is formed directly or indirectly on the second element or the substrate.

It should be understood that the drawings are simplified schematic illustrations of the described devices and may not include well known details to avoid obscuring the features of the embodiments.

It should also be noted that features present in one embodiment may be used with one or more features of another embodiment without departing from the scope of the present disclosure.

It is further noted, that in the various drawings, like reference numbers designate like elements.

As used herein, singular forms are intended to include the plural forms as well, unless the context clearly indicates otherwise.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a first surface and a second surface are “vertically coincident” with each other if the second surface overlies or underlies the first surface and there exists a vertical plane or a substantially vertical plane that includes the first surface and the second surface. A substantially vertical plane is a plane that extends straight along a direction that deviates from a vertical direction by an angle less than 5 degrees. A vertical plane or a substantially vertical plane is straight along a vertical direction or a substantially vertical direction, and may, or may not, include a curvature along a direction that is perpendicular to the vertical direction or the substantially vertical direction.

A package or a chip may include a single semiconductor die (or a “die”) or a plurality of semiconductor dies. A die is the smallest unit that can independently execute external commands or report status. Each die includes one or more planes. Identical concurrent operations can be executed in each plane within a same die. In a memory die, each plane contains a number of memory blocks (or “blocks”), which are the smallest units that can be erased in a single erase operation. Each memory block contains a number of pages, which are the smallest units that can be selected for programming. A page is also the smallest unit that can be selected in a read operation. A memory block includes a plurality of memory cells, which are coupled to a number of word lines (i.e., rows) and a number of bit lines (i.e., columns).

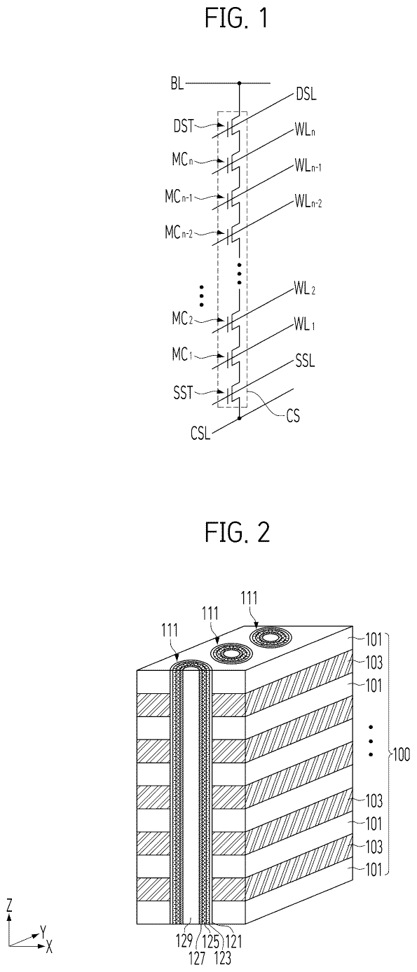

FIG. 1 is a schematic circuit diagram illustrating a memory cell string of a semiconductor memory device. In FIG. 1, a configuration of a memory cell string CS of a three-dimensional NAND device is illustrated.

Referring to FIG. 1, the memory cell string CS may be coupled to a bit line BL and a common source line CSL. Although a single memory cell string CS is illustrated, a plurality of memory cell strings may be coupled in parallel between the bit line BL and the common source line CSL.

The memory cell string CS may include a source select transistor SST, a plurality of memory cells MC1 to MCn, and a drain select transistor DST connected in series between the common source line CSL and the bit line BL.

The source select transistor SST may control the electrical connection between the common source line CSL and the memory cells MC1 to MCn. The source select transistor SST may be coupled to a source select line SSL, and controlled by a source gate signal (voltage) applied to the source select line SSL. Although one source select transistor SST is illustrated in FIG. 1, two or more source select transistors may be disposed in series between the common source line CSL and the memory cells MC1 to MCn.

The memory cells MC1 to MCn may be coupled in series between the source select transistor SST and the drain select transistor DST. The memory cells MC1 to MCn may be coupled to a plurality of word lines WL1 to WLn, and controlled by cell gate signals (voltages) applied to the word lines WL1 to WLn. Each of the memory cells MC1 to MCn may store single-bit data or multi-bit data.

The drain select transistor DST may control the electrical connection between the memory cells MC1 to MCn and the bit line BL. The drain select transistor DST may be coupled to a drain select line DSL, and controlled by a drain gate signal (voltage) applied to the drain select line DSL. Although one drain select transistor DST is illustrated in FIG. 1, two or more source select transistors may be disposed in series between the bit line BL and the memory cells MC1 to MCn.

FIG. 2 is a perspective view illustrating a structure of a semiconductor memory device. In FIG. 2, a partially exploded structure of a three-dimensional NAND device is illustrated.

Referring to FIG. 2, the semiconductor memory device may include a stacked body 100, a blocking insulating layer 121, a data storage layer 123, a tunnel insulating layer 125, and a channel layer 127. The semiconductor memory device may further include a gap-filling layer 129.

The stacked body 100 may include interlayer insulating layers 101 and gate electrodes 103. Each of the interlayer insulating layers 101 and the gate electrodes 103 may be parallel to an X-Y plane. The interlayer insulating layers 101 and the gate electrodes 103 may be stacked in a Z-axis direction perpendicular to the X-Y plane. The interlayer insulating layers 101 and the lines 103 may be alternately stacked.

The interlayer insulating layers 101 may be formed of silicon oxide (e.g., SiO₂).

The gate electrodes 103 may be insulated from each other by the interlayer insulating layers 101. The gate electrodes 103 may be used as the word lines WL1 to WLn, the source select line SSL, and the drain select line SSL described with reference to FIG. 1. The gate electrodes 103 may be formed of doped semiconductor, metal, metal nitride, and metal silicide. For example, the gate electrodes 103 may be formed of a multiple layer of titanium nitride (TiN)/Tungsten (W).

The stacked body 100 may be penetrated by a channel hole 111 extending in the Z-axis direction during the fabrication process. The interlayer insulating layers 101 and the gate electrodes 103 may be defined along a sidewall of the channel hole 111. The channel hole 111 may have various shapes, such as a circle, an oval, a square, a rectangle, and a polygon.

The channel layer 127 may be formed of semiconductor, such as polysilicon or the like. The channel layer 127 may extend in the Z-axis direction along the sidewall of the channel hole 111. The channel layer 127 may form a channel area of the memory cell string CS illustrated in FIG. 1.

The blocking insulating layer 121, the data storage layer 123, and the tunnel insulating layer 125 may be interposed between the stacked body 100 and the channel layer 127. The blocking insulating layer 121, the data storage layer 123, and the tunnel insulating layer 125 may be referred to as a memory layer or an ONO layer.

The blocking insulating layer 121 may include a single layer or multiple layers. The blocking insulating layer 121 may include a silicon oxide layer or a silicon oxide/metal oxide layer. The metal oxide layer (e.g., aluminum oxide, Al₂O₃) may have a higher dielectric constant (i.e., high-k) than that of the silicon oxide layer.

The data storage layer 123 may include a silicon nitride layer (e.g., Si₃N₄). The data storage layer 123 may be referred to as a charge trap layer.

The tunnel insulating layer 125 may include an oxide layer (e.g., silicon oxide, SiO₂) or metal organic frameworks (MOF).

The channel layer 127, the tunnel insulating layer 125, the data storage layer 123, and the blocking insulating layer 121 may be formed in various structures.

In the illustrated embodiment of FIG. 2, the blocking insulating layer 121, the data storage layer 123, and the tunnel insulating layer 125 may extend in the Z-axis direction along the sidewall of the channel layer 127. However, at least one of the blocking insulating layer 121, the data storage layer 123, and the tunnel insulating layer 125 may be disposed in pocket areas in which the gate electrodes 103 are recessed.

Meanwhile, in order to increase the integration in a three-dimensional NAND device, various scaling schemes have been developed. For example, the scaling schemes include a logical scaling (e.g., a single-level cell (SLC), a multi-level cell (MLC), a triple-level cell (TLC), a quad-level cell (QLC), a penta-level cell (PLC)), a vertical scaling (e.g., 100 stacks (tiers), 200 stacks, 300 stacks, 400 stacks), a lateral scaling (e.g., 3 rows between a slit to a slit as one block, 9 rows, 19 rows, in which higher rows mean higher density), and a structural scaling (e.g., 4 dimension (4D), Periphery under Cell Array (PUA), Hybrid Wafer Bonding (HWB)).

These schemes reached their limits in terms of physical and cost issues. To overcome the limitations, additional physical scaling methods are being developed through the formation of multiple cells. Schemes of fabricating multiple cells based on the cutting of channel area are under consideration. Such schemes may be referred to as multi-site or multi-slit cells (MSC). MSC technology can significantly improve the cell program speed in logic scaling and increase the cell density.

However, since the MSC technology is based on the cutting of the channel area (i.e., channel separation), sufficient channel area may not be provided, and therefore enough channel current (i.e., string current) during a program, read, or erase operation may not be secured. In implementing the MSC technology, an oval-shaped cell structure is proposed while using less curvature area for a cell width which can secure a sufficient channel area.

Polycrystalline silicon (polysilicon, poly-Si, or simply poly) is generally used as a channel layer. A thickness of the channel layer needs to be thin for the lower trap density which directly affects the string current. Further, low contact resistance of a channel poly plug to a bit line (metal) contact is essential to maintain a reasonable amount of the string current to benefit from a large channel area. However, the thin channel layer (poly) presented a challenge in forming a reliable metal contact directly to the thin channel layer because of the limited channel to bit line contact area.

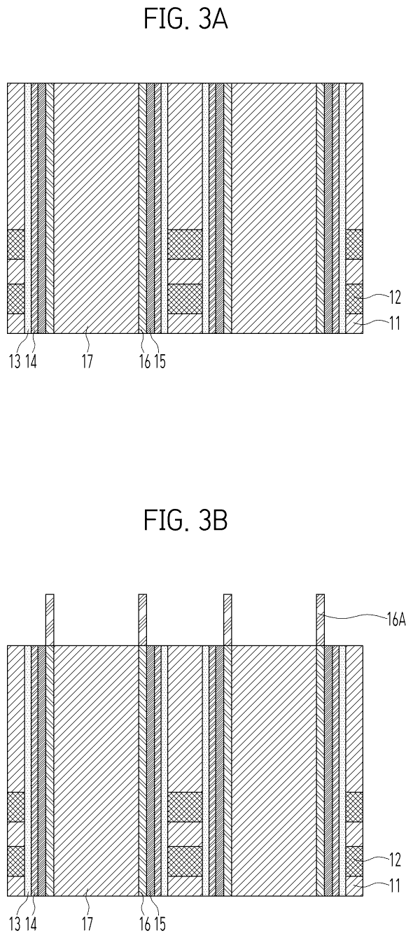

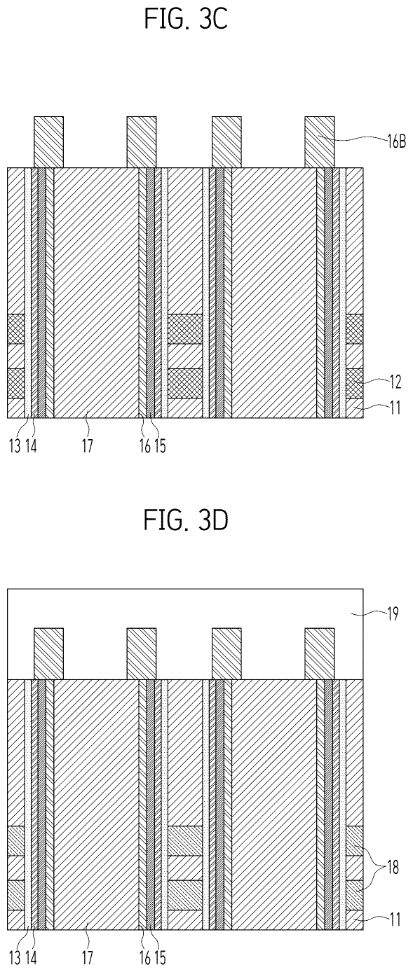

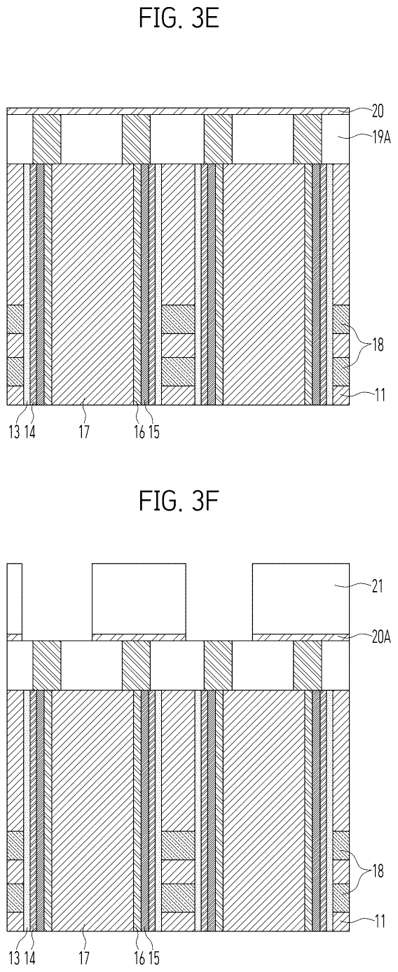

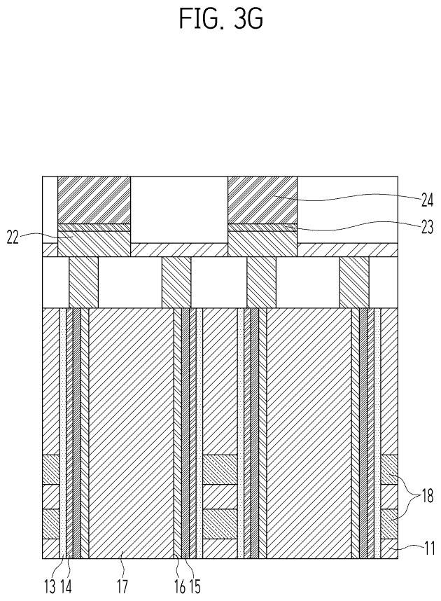

FIGS. 3A to 3G are cross-sectional views illustrating a method of fabricating a three-dimensional semiconductor memory device, in accordance with an embodiment of the present disclosure.

Referring to FIG. 3A, interlayer insulating layers 11 and sacrificial layers 12 may be alternately deposited on a substrate (not illustrated) to form a stack structure.

The number of stacks of the interlayer insulating layers 11 and the sacrificial layers 12 may correspond to the number of transistors included in a single cell string (see FIG. 1).

The substrate may include a silicon wafer. The substrate may further include various elements and interlayer insulating layers formed thereon.

Each of the interlayer insulating layers 11 may include an oxide layer (e.g., SiO₂).

Each of the sacrificial layers 12 may include a nitride layer (e.g., SiN). The thickness of the sacrificial layers 12 may correspond to the thickness of gate electrodes (e.g., WLs, SSL/DSL).

Subsequently, a channel hole is formed penetrating the stack structure by etching the interlayer insulating layers 11 and the sacrificial layers 12 included in the first to third stack structures. A dry etching process may be performed to form the channel hole. The channel hole may have a shape of an oval which is suitable for the MSC formation. However, the channel hole may have various shapes, such as a circle, a square, a rectangle, and a polygon.

Subsequently, a blocking insulating layer 13, a data storage layer 14, and a tunnel insulating layer 15 may be formed on a sidewall of the channel hole. The blocking insulating layer 13, the data storage layer 14, and the tunnel insulating layer 15 may be sequentially and conformably deposited on the sidewall of the channel hole.

The blocking insulating layer 13 may include a single layer or multiple layers. The blocking insulating layer 13 may include a silicon oxide (e.g., SiO₂) layer or a silicon oxide/metal oxide (e.g., aluminum oxide, Al₂O₃) layer.

The data storage layer 14 may include a silicon nitride (e.g., Si₃N₄) layer.

The tunnel insulating layer 15 may include an oxide (e.g., silicon oxide, SiO₂) layer or metal organic frameworks (MOF) layer.

Subsequently, a channel layer 16 may be formed on the tunnel insulating layer 15. The channel layer 16 may be conformally deposited on the tunnel insulating layer 15. Such a structure is referred to as a continuous cell structure.

The channel layer 16 may include a polysilicon layer. The channel layer 16 may include other materials having high mobility such as crystalline silicon, III-V compound semiconductor, graphene, and transition metal dichalcogenides (TMD).

The channel layer 16, the tunnel insulating layer 15, the data storage layer 14, and the blocking insulating layer 13 may be formed as various structures.

In some embodiments, at least one of the blocking insulating layer 13, the data storage layer 14, and the tunnel insulating layer 15 may be disposed in pocket areas in which the sacrificial layers 12 are recessed. To this end, an isotropic etching process may be additionally performed on the sacrificial layers 12 after the channel hole is formed, and etch back process(es) may be additionally performed to form at least one of the blocking insulating layer 13, the data storage layer 14, and the tunnel insulating layer 15 in the pocket areas. Such a structure is referred to as a discrete cell structure.

Subsequently, a gap-filling layer 17 may be formed to fill the remaining channel hole. The gap-filling layer 17 may be formed of silicon oxide (e.g., SiO₂).

Referring to FIG. 3B, the uppermost interlayer insulating layer 11, the blocking insulating layer 13, the data storage layer 14, the tunnel insulating layer 15, and the gap-filling layer 17 may be recessed. An etch-back process may be performed to recess the dielectric layers 11, 13, 14, 15, and 17. The etch-back process may be performed on the dielectric layers 11, 13, 14, 15, and 17 with high etch selectivity to the channel layer (i.e., polysilicon layer) 16. As a result of the etch-back process, the channel layer 16 is exposed with a height ranging from 20 to 100 nm.

Subsequently, an ion implantation or a plasma treatment may be performed on the exposed polysilicon layer 16 to form an amorphized silicon layer 16A. In a case where the ion implantation is applied to the amorphization, a tilt ion implantation may be performed. For example, a low-energy and low-current ion implantation with tilt angle equal to or less than 4° and 180° twist angle. Further, a low-pressure and high-power plasma implantation may be performed.

Referring to FIG. 3C, a selective silicon epitaxial growth (SEG) may be performed on the amorphized silicon layer 16A. For example, a standard fast growth rate condition for the SEG may be applied with a pre-cleaning process. The amorphized silicon layer 16A may be grown and enlarged in all directions to form a silicon mesa (i.e., a mesa structure) 16B. The silicon mesa 16B may have a width 5 times greater than a width of the amorphized silicon layer 16A. For example, a target width of the silicon mesa 16B may be 10 to 20 nm.

Though not illustrated in the drawings, after forming such self-aligned silicon mesa 16B with enlarged size, a liner oxide layer and a gap-filling oxide layer may be formed over the structure in which the silicon mesa 16B is formed, followed by chemical-mechanical polishing (CMP) process. Then, an interlayer insulating layer (e.g., oxide layer) may be deposited for subsequent processes (i.e., a slit etch and a gate electrode replacement). The slit etch may be performed to form a slit for the gate electrode replacement, and then the sacrificial layers 12 may be selectively removed (or exhumed). The sacrificial layers 12 may be removed by an isotropic etching process using the slit exposing the sacrificial layers 12.

Referring to FIG. 3D, gate electrodes 18 may be formed to fill an area from which the sacrificial layers 12 are removed. That is, the gate electrodes 18 may replace the sacrificial layers 12. For example, the gate electrodes 18 may include one of TiN, TiAlN, TiN/W, WN/W, TaN, HfN, Molybdenum (Mo), Ruthenium (Ru), and a combination thereof. The gate electrodes 18 may serve as source select lines, word lines, or drain select lines.

In the figure, reference numeral 19 indicates a gap-filling/interlayer insulating layer remaining after the metallization.

Referring to FIG. 3E, the gap-filling/interlayer insulating layer 19 may be planarized to expose a top surface of the silicon mesa 16B. A chemical-mechanical polishing (CMP) process may be performed for the planarization. In the figure, reference numeral 19A indicates the planarized gap-filling/interlayer insulating layer.

Subsequently, an etch-stop layer 20 may be formed on the planarized structure. For example, the etch-stop layer 20 may be formed of silicon nitride (e.g., SiN).

Referring to FIG. 3F, an interlayer insulating layer 21 is formed on the etch-stop layer 20. Then, the interlayer insulating layer 21 and the etch-stop layer 20 may be patterned to form a contact hole exposing the top surface of the silicon mesa 16B. The interlayer insulating layer 21 and the etch-stop layer 20 may be etched using different plasma sources in the same chamber. A post-etch cleaning process may be performed. Since an etching process is performed using the etch-stop layer 20, the silicon mesa 16B may be protected from damages generated during the etching processes.

In the figure, reference numeral 20A indicates a patterned etch-stop layer.

Referring to FIG. 3G, a doped polysilicon layer 22 may be formed on the structure in which the contact hole is formed, and then may be recessed to be remaining in the bottom of the contact hole to form a poly contact plug. For example, n-type in-situ doped polysilicon may be deposited as the doped polysilicon layer 22, and an etch-back process may be performed to recess the doped polysilicon layer 22.

Subsequently, a metallization of the contact plug may be processed. That is, an adhesion layer 23 and a metal layer 24 may be filled in the contact hole. To this end, deposition and recess (e.g., an etch-back process) of the adhesion layer 23, and deposition and planarization (e.g., a CMP process) of the metal layer 24 may be performed. For example, Ti/TiN may be used as the adhesion layer 23, tungsten (W) may be used as the metal layer 24. During the deposition of the Ti/TiN, silicide may be formed on the top surface of the doped polysilicon layer 22 to achieve the low metal to poly contact resistance.

Then, bit line formation may be processed. Bit lines may be coupled with the metallized contact plug though a via contact.

According to the above-described embodiments of the present disclosure, contact formation by enlargement of a thin channel poly plug and a combination of poly and metal contact plug can secure reasonable size for a bit line contact to satisfy both lower contact resistance and electric current crowding concerns during program and erase operations. Further, the enlarged channel poly plug can be provided without complicated and expensive processes.

The embodiment of the present disclosure can be applied to a multi-site cells (MSC) scheme as well as a general 3D cell scheme. Since the MSC scheme using the channel separation (cutting) requires a thinner channel layer for the lower trap density, securing a reliable channel to metal contact is more important than when applied to the general 3D cell scheme.

While the embodiments of the present disclosure contain many specifics, these should not be construed as limitations on the scope of the present disclosure or of what may be claimed, but rather as descriptions of features that may be specific to particular embodiments of the present disclosure. Certain features that are described in the context of separate embodiments can also be implemented in combination to form a single embodiment. Conversely, various features that are described in the context of a single embodiment can also be implemented in multiple embodiments separately or in any suitable sub-combination. Moreover, although features may be described above as acting in certain combinations, one or more features from a combination can in some cases be excised from the combination, and the combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in the present disclosure should not be understood as requiring such separation in all embodiments.

Only a few implementations and embodiments are described and other implementations, embodiments, enhancements and variations can be made based on what is described and illustrated in the present disclosure. Furthermore, the embodiments may be combined to form additional embodiments.

What is claimed is:

1. A method of fabricating a three-dimensional semiconductor memory device, the method comprising:
forming a stack structure including alternately stacked interlayer insulating layers and sacrificial layers on a substrate;
forming a channel hole penetrating the stack structure;
forming a memory layer and a channel layer vertically disposed in the channel hole;
forming a gap-filling layer to fill a remainder of the channel hole;
forming an exposed portion of the channel layer by recessing an uppermost interlayer insulating layer of the interlayer insulating layers, the memory layer, and the gap-filling layer;
forming a mesa structure by performing an epitaxial growth process on the exposed portion of the channel layer;
replacing the sacrificial layers with gate electrode layers; and
forming a contact plug disposed to contact the mesa structure.

2. The method of claim 1, wherein the channel layer includes a polysilicon.

3. The method of claim 2, wherein the performing of the epitaxial growth process comprises:
amorphizing the exposed channel layer to form an amorphized silicon; and
performing a selective silicon epitaxial growth process on the amorphized silicon.

4. The method of claim 3, wherein the amorphizing of the exposed channel layer comprises performing an ion implantation or a plasma treatment on the exposed channel layer.

5. The method of claim 2, wherein the forming of the contact plug comprises:
forming a first interlayer insulating layer to cover the mesa structure;
planarizing the first interlayer insulating layer to expose a top surface of the mesa structure;
forming an etch stop layer and a second interlayer insulating layer to cover the top surface of the mesa structure;
patterning the second interlayer insulating layer and the etch stop layer to form a contact hole; and
forming a doped polysilicon layer and a metal layer to fill the contact hole.

6. The method of claim 5, wherein the metal layer includes a tungsten (W).

7. The method of claim 6, wherein the metal layer further includes an adhesion layer disposed between the doped polysilicon layer and the tungsten.

8. The method of claim 7, wherein the adhesion layer includes Ti/TIN.

9. A three-dimensional memory device comprising:
a plurality of interlayer insulating layers and a plurality of gate electrode layers, which are alternately stacked to form a stack structure;
a memory layer and a channel polysilicon layer vertically disposed within the stack structure;
a silicon mesa disposed to be connected to the channel polysilicon layer, the silicon mesa being formed by a selective silicon epitaxial growth of the channel polysilicon layer; and
a contact plug disposed to contact the silicon mesa.

10. The three-dimensional memory device of claim 9, wherein the contact plug includes a doped polysilicon layer and a metal layer which are stacked.

11. The three-dimensional memory device of claim 10, wherein the metal layer includes Ti/TIN/W.
